(19) United States
(12) Patent Application Publication
(10) Pub. No.: US 2015/0202656 A1
(43) Pub. Date: Jul. 23, 2015

(54) FLEXIBLE TRANSDUCER

(71) Applicant: SUMITOMO RIKO COMPANY LIMITED, Aichi-ken (JP)

(72) Inventors: Wataru TAKAHASHI, Aichi-ken (JP); Hitoshi YOSHIKAWA, Aichi-ken (JP); Shigeaki TAKAMATSU, Aichi-ken (JP)

(73) Assignee: SUMITOMO RIKO COMPANY LIMITED, Aichi-ken (JP)

(21) Appl. No.: 14/674,231

(22) Filed: Mar. 31, 2015

Related U.S. Application Data
(63) Continuation of application No. PCT/JP2013/083911, filed on Dec. 18, 2013.

(30) Foreign Application Priority Data
Jan. 30, 2013 (JP) 2013-015193

(51) Int. Cl. B06B 1/06; H01L 51/10

(52) U.S. Cl. CPC B06B 1/06; H01L 51/102

(57) ABSTRACT

A flexible transducer includes: a dielectric layer including a semiconductor-containing layer that contains an elastomer and at least one of an inorganic semiconductor and an organic semiconductor; and a pair of electrodes disposed with the dielectric layer interposed therebetween, and containing a binder and a conductive material. The semiconductor-containing layer has a large dielectric constant and has high insulation properties. According to the flexible transducer, a large voltage can be applied between the electrodes, and a high output can be obtained.

### TECHNICAL FIELD

The present invention relates to flexible transducers including an elastomer material.

### BACKGROUND ART

An actuator, sensor, power-generating element, etc. which carries out conversion between mechanical energy and electrical energy, or a speaker, microphone, etc. which carries out conversion between acoustic energy and electrical energy are known as transducers. Polymer materials such as a dielectric elastomer are useful in forming highly flexible, small, lightweight transducers.

For example, a flexible transducer can be formed by disposing a pair of electrodes on both surfaces in the thickness direction of a sheet-like dielectric layer formed of a dielectric elastomer. This type of transducer can generate a force by electric charges between the electrodes, detects electric charges produced by deformation, and can generate electric power. For example, if an applied voltage between the pair of electrodes is increased, electrostatic attraction between the electrodes increases. Accordingly, the dielectric layer interposed between the electrodes is compressed in the thickness direction, and the thickness of the dielectric layer is reduced. As the thickness of the dielectric layer is reduced, the dielectric layer is extended accordingly in a direction parallel to the electrode faces. If the applied voltage between the pair of electrodes is reduced, electrostatic attraction between the electrodes decreases. Accordingly, the compressive force applied to the dielectric layer in the thickness direction is reduced, and the thickness of the dielectric layer is increased due to its elastic restoring force. As the thickness of the dielectric layer is increased, the dielectric layer is contracted accordingly in the direction parallel to the electrode faces. The flexible transducer can thus be used as an actuator by using extension and contraction of the dielectric layer which occur according to a change in applied voltage.

The force that is output from the actuator and the displacement amount of the actuator are determined by the magnitude of the applied voltage and the dielectric constant of the dielectric layer. That is, the larger the applied voltage and the dielectric constant of the dielectric layer, the larger the generated force and the displacement amount of the actuator. Silicone rubber having high resistance to dielectric breakdown, acrylic rubber and nitrile rubber having a large dielectric constant, etc. are used as the material of the dielectric layer (see, e.g., Patent Document 1).

### RELATED ART DOCUMENTS

### Patent Documents

[Patent Document 1] Japanese Translation of PCT International Application Publication No. 2003-506858

[Patent Document 2] Japanese Patent Application Publication No. 2002-353521 (JP 2002-353521 A)

[Patent Document 3] Japanese Translation of PCT International Application Publication No. 2001-523040

[Patent Document 4] Japanese Patent Application Publication No. 2008-211879 (JP 2008-211879 A)

### SUMMARY OF THE INVENTION

### Problem to be Solved by the Invention

In a dielectric layer made of silicone rubber, a dielectric breakdown is less likely to occur even if a large voltage is applied. However, silicone rubber has small polarity. That is, silicone rubber has a small dielectric constant. Accordingly, in the case where an actuator formed by using a dielectric layer made of silicone rubber, only small electrostatic attraction occurs in response to an applied voltage. A desired force and displacement amount therefore cannot be obtained by practical voltages.

Acrylic rubber and nitrile rubber have a higher dielectric constant than silicone rubber. Accordingly, if acrylic rubber etc. is used as the material of the dielectric layer, electrostatic attraction that occurs in response to an applied voltage is increased as compared to the case where silicone rubber is used as the material of the dielectric layer. However, acrylic rubber etc. has lower electrical resistance than silicone rubber. Accordingly, a dielectric breakdown of the dielectric layer tends to occur if the dielectric layer is made of acrylic rubber etc. Moreover, since a current tends to flow in the dielectric layer upon voltage application (i.e., a leak current is large), electric charges are less likely to be accumulated in the interface between the dielectric layer and the electrodes. Accordingly, electrostatic attraction is small despite the large dielectric constant, and a sufficient force and displacement amount cannot be obtained. It is therefore difficult to implement a dielectric layer that satisfies both electrostatic attraction and resistance to dielectric breakdown by using only the elastomer.

In sensors that detect capacitance, the dielectric layer need to have a large dielectric constant in order to increase sensitivity. At the same time, high insulation properties are required in order to hold electric charges. The ability to hold a large amount of electric charges is also required in order to improve performance of power generating elements and speakers. It is difficult to implement both a high dielectric constant and high insulation properties by using only the elastomer.

The present invention was developed in view of the above circumstances, and it is an object of the present invention to provide a transducer that includes a dielectric layer containing an elastomer, that has high resistance to dielectric breakdown, and that is capable of outputting a high power.

### Means for Solving the Problem

A flexible transducer according to the present invention is characterized by including: a dielectric layer including a semiconductor-containing layer that contains an elastomer and at least one of an inorganic semiconductor and an organic semiconductor; and a pair of electrodes disposed with the dielectric layer interposed therebetween, and containing a binder and a conductive material.

In the flexible transducer of the present invention, the dielectric layer interposed between the pair of electrodes has the semiconductor-containing layer containing an elastomer and at least one of an inorganic semiconductor and an organic semiconductor (hereinafter sometimes collectively referred to as the “semiconductor”). The semiconductor includes an n-type semiconductor having free electrons (negatively charged particles) and a p-type semiconductor having holes (positively charged particles). For example, if a voltage is applied to an n-type semiconductor-containing layer containing an n-type semiconductor, free electrons move and electric charges are thus unevenly present in the n-type semiconductor. If a voltage is applied to a p-type semiconductor-containing layer containing a p-type semiconductor, holes move and electric charges are thus unevenly present in the p-type semiconductor. The dielectric constant is increased by polarization in the semiconductor. Moreover, free electrons or holes (carriers) are less likely to flow as a current in the dielectric layer because the insulating elastomer that is a base material serves as a barrier. Accordingly, although the semiconductor-containing layer has a large dielectric constant, a dielectric breakdown of the semiconductor-containing layer is less likely to occur.

Although the dielectric layer may be formed of only the semiconductor-containing layer (either a single layer or a plurality of layers), the dielectric layer may further include another layer in addition to the semiconductor-containing layer. For example, a high resistance layer having high electrical resistance can be placed on the semiconductor-containing layer. In this case, since the high resistance layer adjoining the semiconductor-containing layer has high electrical resistance, a large amount of electric charges is accumulated in the interface between the semiconductor-containing layer and the high resistance layer. Accordingly, large electrostatic attraction that compresses the semiconductor-containing layer and the high resistance layer occurs, and high power can be output.

As described above, the flexible transducer of the present invention has the semiconductor-containing layer as the dielectric layer and can therefore cause large electrostatic attraction in the dielectric layer. The dielectric layer has high dielectric breakdown strength. Therefore, according to the flexible transducer of the present invention, a large voltage can be applied and high power can be output. In the case where the flexible transducer of the present invention is used as a capacitive sensor, resolution to displacement can be improved due to the large capacitance of the semiconductor-containing layer.

For example, ion components may be added to the elastomer in order to increase the dielectric constant of the dielectric layer. In this case, molecules of the ion components are reversed and polarized in response to voltage application. A large amount of electric charges can therefore be generated in the dielectric layer. However, ion molecules themselves need be reversed for ionic polarization. In general, in dielectric materials in which polarization inversion occurs due to reversal of a substance itself, the rate at which the substance is reversed is not able to catch up with the frequency as the frequency becomes higher. Accordingly, if an AC voltage of a high frequency is applied, polarization cannot follow a change in voltage. The effect of increasing the dielectric constant due to addition of the ion components can be obtained only up to a frequency as low as about 10 Hz.

In this regard, in the semiconductor-containing layer of the present invention, charge density is increased due to carriers (holes or free electrons) of the semiconductor. Movement of carriers does not involve reversal of a substance like ion polarization. Accordingly, the effect of improving the dielectric constant due to polarization can be obtained even if the applied voltage has high frequencies. The flexible transducer of the present invention is therefore also suitable for applications in which an AC voltage of high frequencies is applied.

In the case where an ion-containing layer containing the ion components and the high resistance layer are stacked, the ion components tend to diffuse into the high resistance layer. This reduces the electrical resistance of the high resistance layer, which may cause a dielectric breakdown. If a current flows in the high resistance layer, the high resistance layer may break down by Joule heat that is generated.

In this regard, in the semiconductor-containing layer of the present invention, carriers of the semiconductor move in response to voltage application, but the semiconductor itself (fixed charges) does not move. Accordingly, even if the semiconductor-containing layer and the high resistance layer are stacked, no change in the semiconductor-containing layer and the high resistance layer occurs with time due to movement of the semiconductor itself. Reduction in electrical resistance of the high resistance layer and a dielectric breakdown are therefore less likely to occur.

Patent Document 2 describes a thermoelectric generation module in which an n-type thermoelectric semiconductor base is bonded to a p-type thermoelectric semiconductor base. The thermoelectric generation module described in Patent Document 2 uses Pertier effect or Seebeck effect, and is different from the flexible transducer of the present invention which uses an electrostrictive effect. The n-type thermoelectric semiconductor base described in Patent Document 2 is a base produced by adding n-type thermoelectric semiconductor particles to conductive plastic with volume resistivity of 10⁻⁴ to 10³ Ω·cm, namely synthetic rubber having conductive particles therein. Similarly, the p-type thermoelectric semiconductor base is a base produced by adding p-type thermoelectric semiconductor particles to the conductive plastic. The n-type thermoelectric semiconductor base and the p-type-thermoelectric-semiconductors base are also different from the semiconductor-containing layer of the present invention in that conductive properties are provided by the conductive particles. Patent Document 3 describes a composition having an insulating binder, conductive particles, and semiconductor particles. The composition described in Patent Document 3 is used to protect electronic parts against an electric overload transient phenomenon, and is different from the semiconductor-containing layer of the present invention in that conductive properties are provided by the conductive particles. Patent Document 4 describes an electrostrictive actuator including an extendable/contractible body, a semiconductor layer, and a pair of electrodes. The semiconductor layer is different from the semiconductor-containing layer of the present invention in that the semiconductor layer contains a conductive substance such as carbon powder and does not contain a semiconductor.

### BRIEF DESCRIPTION OF THE DRAWINGS

FIG. 1 is a schematic sectional view of a transducer according to a first embodiment.

FIG. 2 is a schematic sectional view of a transducer according to a second embodiment.

FIG. 3 is a schematic sectional view of a transducer according to a third embodiment.

FIG. 4 is a schematic sectional view of a transducer according to a fourth embodiment.

FIG. 5 is a perspective view of a speaker as a fifth embodiment of a transducer of the present invention.

FIG. 6 is a sectional view taken along line VI-VI in FIG. 5.

FIGS. 7A and 7B show schematic sectional views of a power generating element as a sixth embodiment of the transducer of the present invention, where FIG. 7A shows an extended state, and FIG. 7B shows a contracted state.

FIG. 8 is a top view of a capacitive sensor as a seventh embodiment of the transducer of the present invention.

FIG. 9 is a sectional view taken along line IX-IX in FIG. 8.

FIG. 10 is a front view showing the front side of an actuator attached to a measuring apparatus.

FIG. 11 is a sectional view taken along line XI-XI in FIG. 10.

FIG. 12 is a top view of an actuator used for evaluation experiments.

FIG. 13 is a sectional view taken along line XIII-XIII in FIG. 12.

### DESCRIPTION OF THE REFERENCE NUMERALS

1: transducer, 10: dielectric layer, 11a, 11b: electrode, 12: n-type semiconductor-containing layer, 13: p-type semiconductor-containing layer, 14: high resistance layer.

2: capacitive sensor (transducer), 20: dielectric layer, 21a, 21b: electrode, 22a, 22b: wire, 23a, 23b: cover film, 24: connector, 3: power generating element (transducer), 30: dielectric layer, 31a, 31b: electrode, 32a to 32c: wire.
4: speaker (transducer), 40a: first outer frame, 40b: second outer frame, 41a: first inner frame, 41b: second inner frame, 42a: first dielectric layer, 42b: second dielectric layer, 43a: first outer electrode, 43b: second outer electrode, 44a: first inner electrode, 44b: second inner electrode, 45a: first diaphragm, 45b: second diaphragm, 430a, 430b, 440a, 440b: terminal, 460: bolt, 461: nut, 462: spacer.
5: actuator, 50: dielectric layer, 51a, 51b: electrode, 52: upper chuck, 53: lower chuck. 6: actuator, 60: dielectric layer, 61a, 61b: electrode, 62: power supply, 63: displacement meter, 610a, 610b: terminal portion, 630: marker

### MODES FOR CARRYING OUT THE INVENTION

Embodiments of a flexible transducer according to the present invention will be described below. The flexible transducer of the present invention is not limited to the following embodiments, and can be carried out in various modified or improved forms etc. that may occur to those skilled in the art without departing from the spirit and scope of the present invention. The flexible transducer of the present invention includes a dielectric layer and a pair of electrodes disposed with the dielectric layer interposed therebetween.

<Dielectric Layer>

The dielectric layer is disposed between the pair of electrodes. Either one dielectric layer or more than one dielectric layer may be provided as long as the dielectric layer has a semiconductor-containing layer. An example of the configuration of the dielectric layer will be described with respect to an example in which the flexible transducer of the present invention is used as an actuator. As shown in fifth to seventh embodiments below, a configuration similar to that described below can be used when using the flexible transducer of the present invention as a speaker, a power generating element, a sensor, etc.

### First Embodiment

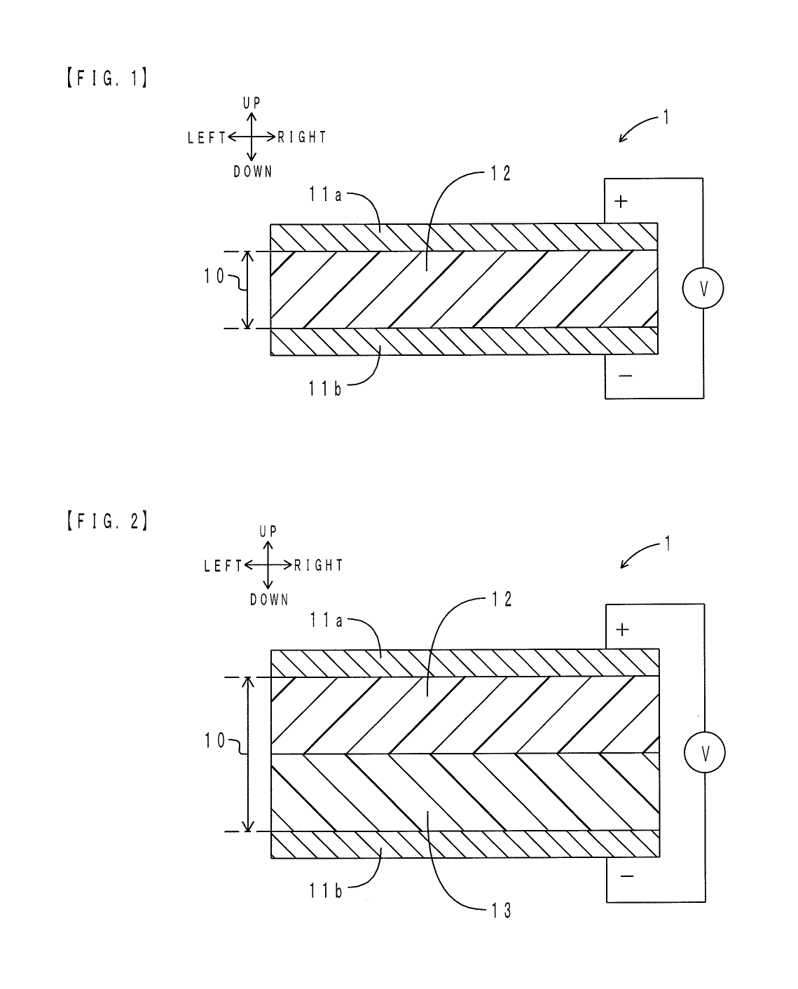

The configuration and operation of a flexible transducer of the present embodiment (hereinafter simply referred to as the “transducer” in the embodiments) will be described. FIG. 1 is a schematic sectional view of the transducer of the present embodiment. As shown in FIG. 1, a transducer 1 includes a dielectric layer 10 and a pair of electrodes 11a, 11b. The dielectric layer 10 is formed of an n-type semiconductor-containing layer 12. The n-type semiconductor-containing layer 12 contains nitrile rubber and P-doped SnO₂ particles as n-type semiconductor inorganic particles. Nitrile rubber is included in the elastomer of the present invention. The electrode 11a is a positive electrode and is disposed on the upper surface of the n-type semiconductor-containing layer 12. The electrode 11b is a negative electrode and is disposed on the lower surface of the n-type semiconductor-containing layer 12.

When a voltage is applied between the pair of electrodes 11a, 11b, free electrons of the n-type semiconductor inorganic particles move toward the positive electrode 11a, causing polarization in the n-type semiconductor inorganic particles. The n-type semiconductor-containing layer 12 therefore has increased charge density and an increased dielectric constant. Accordingly, large electrostatic attraction occurs between the pair of electrodes 11a, 11b so as to compress the n-type semiconductor-containing layer 12. The free electrons are less likely to flow as a current because nitrite rubber that is a base material serves as a barrier. A dielectric breakdown of the n-type semiconductor-containing layer 12 is therefore less likely to occur.

Accordingly, an applied voltage can be increased and a large force and a large displacement amount can be obtained according to the transducer 1. The transducer 1 is also highly durable.

### Second Embodiment

The configuration and operation of a transducer of the present embodiment will be described. FIG. 2 is a schematic sectional view of the transducer of the present embodiment. Members corresponding to those in FIG. 1 are denoted with the same reference characters. As shown in FIG. 2, a transducer 1 includes a dielectric layer 10 and a pair of electrodes 11a, 11b. The dielectric layer 10 is formed of an n-type semiconductor-containing layer 12 and a p-type semiconductor-containing layer 13. The n-type semiconductor-containing layer 12 is placed on the upper surface of the p-type semiconductor-containing layer 13. The p-type semiconductor-containing layer 13 contains nitrile rubber and nickel oxide particles as p-type semiconductor inorganic particles. The electrode 11a is a positive electrode and is disposed on the upper surface of the n-type semiconductor-containing layer 12. The electrode 11b is a negative electrode and is disposed on the lower surface of the p-type semiconductor-containing layer 13.

When a voltage is applied between the pair of electrodes 11a, 11b, free electrons of n-type semiconductor inorganic particles in the n-type semiconductor-containing layer 12 move toward the positive electrode 11a, causing polarization in the n-type semiconductor inorganic particles. Moreover, holes of the p-type semiconductor inorganic particles in the p-type semiconductor-containing layer 13 move toward the negative electrode 11b, causing polarization in the p-type semiconductor inorganic particles. The n-type semiconductor-containing layer 12 and the p-type semiconductor-containing layer 13 therefore have increased charge density and an increased dielectric constant. Accordingly, large electrostatic attraction occurs between the pair of electrodes 11a, 11b so as to compress the n-type semiconductor-containing layer 12 and the p-type semiconductor-containing layer 13. The free electrons are less likely to flow as a current because nitrile rubber that is a base material serves as a barrier. A dielectric breakdown of the n-type semiconductor-containing layer 12 and the p-type semiconductor-containing layer 13 is therefore less likely to occur.

### Third Embodiment

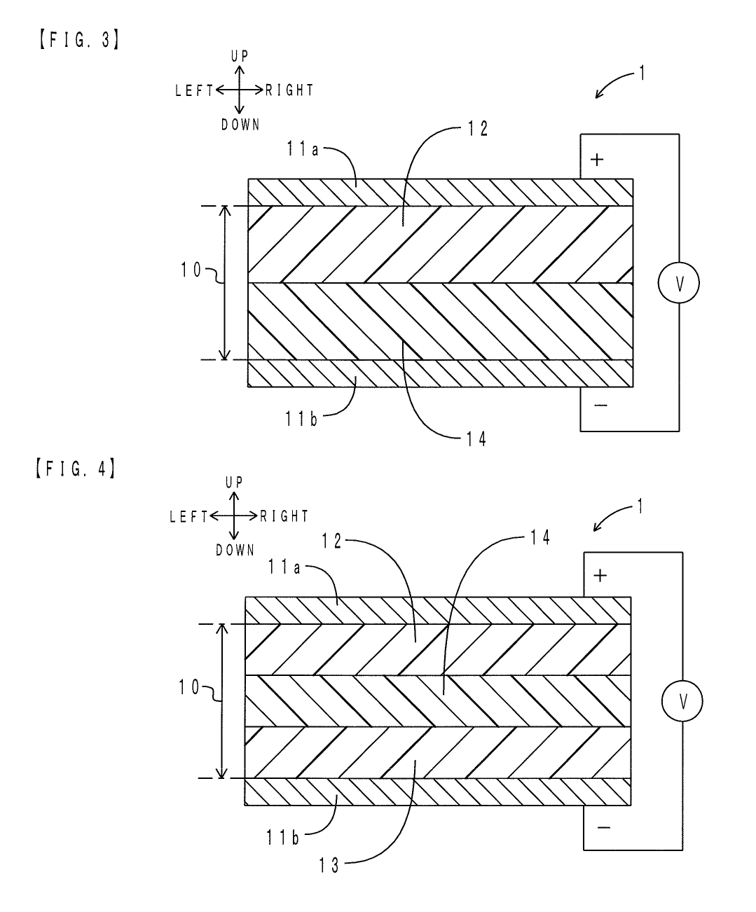

The configuration and operation of a transducer of the present embodiment will be described. FIG. 3 is a schematic sectional view of the transducer of the present embodiment. Members corresponding to those in FIG. 1 are denoted with the same reference characters. As shown in FIG. 3, a transducer 1 includes a dielectric layer 10 and a pair of electrodes 11a, 11b. The dielectric layer 10 is formed of an n-type semiconductor-containing layer 12 and a high resistance layer 14. The n-type semiconductor-containing layer 12 is placed on the upper surface of the high resistance layer 14. The high resistance layer 14 contains nitrile rubber and TiO₂ as insulating particles. The volume resistivity of the high resistance layer 14 is 8×10¹³ Ω·cm. The electrode 11a is a positive electrode and is disposed on the upper surface of the n-type semiconductor-containing layer 12. The electrode 11b is a negative electrode and is disposed on the lower surface of the high resistance layer 14.

When a voltage is applied between the pair of electrodes 11a, 11b, free electrons of n-type semiconductor inorganic particles in the n-type semiconductor-containing layer 12 move toward the positive electrode 11a, causing polarization in the n-type semiconductor inorganic particles. The n-type semiconductor-containing layer 12 therefore has increased charge density and an increased dielectric constant. If the voltage continues to be applied, part of the free electrons of the n-type semiconductor inorganic particles moves into nitrile rubber as a base material. However, the n-type semiconductor inorganic particles as fixed charges hardly move. The high resistance layer 14 has high electrical resistance. Many electric charges are therefore accumulated in the interface between the n-type semiconductor-containing layer 12 and the high resistance layer 14. Accordingly, large electrostatic attraction occurs between the pair of electrodes 11a, 11b so as to compress the n-type semiconductor-containing layer 12 and the high resistance layer 14.

### Fourth Embodiment

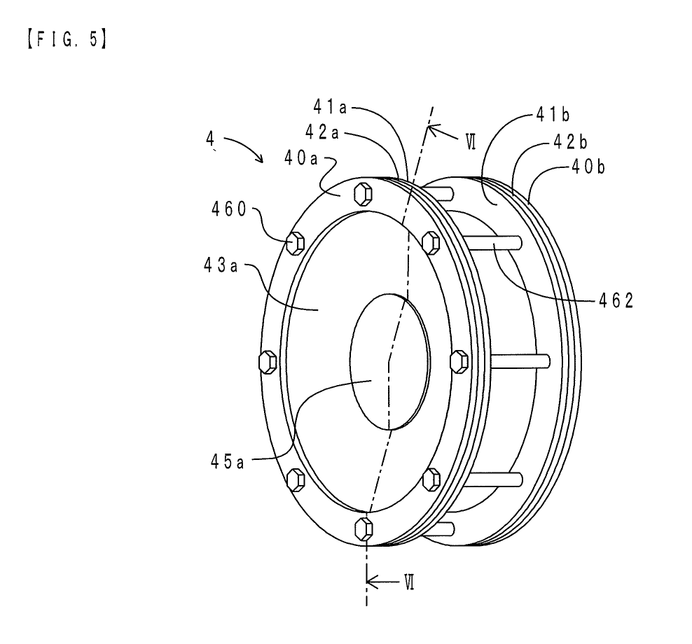

The configuration and operation of a transducer of the present embodiment will be described. FIG. 4 is a schematic sectional view of the transducer of the present embodiment. Members corresponding to those in FIGS. 2 and 3 are denoted with the same reference characters. As shown in FIG. 4, a transducer 1 includes a dielectric layer 10 and a pair of electrodes 11a, 11b. The dielectric layer 10 is formed of an n-type semiconductor-containing layer 12, a p-type semiconductor-containing layer 13, and a high resistance layer 14. The high resistance layer 14 is interposed between the n-type semiconductor-containing layer 12 and the p-type semiconductor-containing layer 13. The electrode 11a is a positive electrode and is disposed on the upper surface of the n-type semiconductor-containing layer 12. The electrode 11b is a negative electrode and is disposed on the lower surface of the p-type semiconductor-containing layer 13.

When a voltage is applied between the pair of electrodes 11a, 11b, polarization occurs in n-type semiconductor inorganic particles in the n-type semiconductor-containing layer 12. Polarization also occurs in p-type semiconductor inorganic particles in the p-type semiconductor-containing layer 13. The n-type semiconductor-containing layer 12 and the p-type semiconductor-containing layer 13 therefore have increased charge density and an increased dielectric constant. If the applied voltage is increased, part of free electrons of the n-type semiconductor inorganic particles moves into nitrile rubber as a base material. However, the n-type semiconductor inorganic particles as positive fixed charges hardly move. Similarly, part of holes of the p-type semiconductor inorganic particles moves into nitrile rubber as a base material. However, the p-type semiconductor inorganic particles as negative fixed charges hardly move. The high resistance layer 14 has high electrical resistance. Many electric charges are therefore accumulated in the interface between the n-type semiconductor-containing layer 12 and the high resistance layer 14 and the interface between the p-type semiconductor-containing layer 13 and the high resistance layer 14. Accordingly, large electrostatic attraction occurs between the pair of electrodes 11a, 11b so as to compress the n-type semiconductor-containing layer 12, the high resistance layer 14, and the p-type semiconductor-containing layer 13.

Each of the layers forming the dielectric layer will be described in detail below.

[Semiconductor-Containing Layer]

The semiconductor-containing layer contains an elastomer and at least one of an inorganic semiconductor and an organic semiconductor. The elastomer includes a crosslinked rubber and a thermoplastic elastomer. One kind of crosslinked rubber or thermoplastic elastomer or a mixture of more than one kind of crosslinked rubber and/or thermoplastic elastomer can be used as the elastomer. The elastomer can be selected as appropriate according to performance required for the transducer. For example, an elastomer having high polarity, namely having a large dielectric constant, is desirable in order to increase electrostatic attraction that occurs upon voltage application. Specifically, an elastomer having a dielectric constant of 2.8 or more (measurement frequency: 100 Hz) is preferred. Examples of the elastomer having a large dielectric constant include nitrile rubber (NBR), hydrogenated nitrile rubber (H-NBR), acrylic rubber, natural rubber, isoprene rubber, an ethylene-vinyl acetate copolymer, an ethylene-vinyl acetate-acrylic acid ester copolymer, butyl rubber, styrene-butadiene rubber, fluororubber, epichlorohydrin rubber, chloroprene rubber, chlorinated polyethylene, chlorosulfonated polyethylene, and urethane rubber. An elastomer modified by introducing functional groups therein etc. may be used. Preferred examples of the modified elastomer include carboxyl group-modified nitrile rubber (X-NBR) and carboxyl group-modified hydrogenated nitrile rubber (XH-NBR). X-NBR and XH-NBR having an acrylonitrile content (bonded AN content) of 33 mass % or more are desirable. The bonded AN content is the proportion of mass of acrylonitrile in the case where the total mass of the rubber is 100 mass %.

An elastomer having a small dielectric constant but having high electrical resistance is desirable as a dielectric breakdown is less likely to occur upon voltage application. Examples of the elastomer having high electrical resistance include silicone rubber and an ethylene-propylene-diene copolymer.

The thermoplastic elastomer is preferred since no crosslinking agent is used for the thermoplastic elastomer and impurities are therefore less likely to enter the thermoplastic elastomer. Examples of the thermoplastic elastomer include a styrene elastomer (SBS, SEBS, SEPS), an olefin elastomer (TPO), a vinyl chloride elastomer (TPVC), a urethane elastomer (TPU), an ester elastomer (TPEE), an amide elastomer (TPAE), and a copolymer or blend thereof.

It is desirable that the inorganic semiconductor include particles of a p-type or n-type semiconductor as an inorganic substance. The p-type or n-type semiconductor can be either an intrinsic semiconductor lightly doped with a predetermined element or a p-type or n-type material such as an oxide and a chalcogenide. Chalcogenides include sulfides, selenides, and tellurides. Among these materials, oxides or sulfides, in particular metal oxides or metal sulfides, are preferred in terms of stability and safety.

Examples of a p-type metal oxide or metal sulfide include a compound containing nickel, a compound containing monovalent copper, and a compound containing cobalt. Specific examples of the p-type metal oxide or metal sulfide include nickel oxide, copper oxide, and a cobalt-sodium composite oxide (e.g., NaₓCoO₄). The metal oxide or metal sulfide may be a metal oxide or metal sulfide whose element is partially substituted, or a metal oxide or metal sulfide lightly doped with a predetermined element.

Examples of an n-type metal oxide include zinc oxide, titanium oxide, zirconium oxide, indium oxide, bismuth oxide, vanadium oxide, tantalum oxide, niobium oxide, tungsten oxide, tin oxide, iron oxide, potassium tantalate, barium titanate, calcium titanate, and strontium titanate. Examples of a metal sulfide include cadmium sulfide, zinc sulfide, and indium sulfide. The metal oxide or metal sulfide may be a metal oxide or metal sulfide whose element is partially substituted, or a metal oxide or metal sulfide lightly doped with a predetermined element.

In order to increase the carrier concentration in the particles to enhance the effect of increasing the dielectric constant, the metal oxide or metal sulfide is desirably a metal oxide or metal sulfide whose element is partially substituted, or a metal oxide or metal sulfide lightly doped with a predetermined element.

In particular, barium titanate doped with La, Nb, Ta, Y, Ca, Mg, or Mn, titanium oxide doped with Nb, Ta, Sb, P, or N, tin oxide doped with P, Sb, or Al, zinc oxide doped with Al or Ga, and indium oxide doped with Sn are preferred. A metal oxide or metal sulfide doped with a plurality of elements may be used. Oxygen deficiency may be caused by reductive annealing etc. to increase the carrier concentration.

The doping amount of each element is determined as appropriate because its optimal value varies according to the base particles to be doped. For example, the doping amount is desirably in the range of 0.01 mol % to 20 mol %, both inclusive. The doping amounts smaller than 0.01 mol % are not very effective in increasing the dielectric constant, and the doping amounts larger than 20 mol % reduce the dielectric constant. The doping amount is more preferably in the range of 0.5 mol % to 10 mol %, both inclusive.

The semiconductor-containing layer may contain either one kind of semiconductor particles or more than one kind of semiconductor particles. Either commercially available particles or particles synthesized by a solid-phase synthesis method, a supercritical hydrothermal synthesis method, a hydrothermal synthesis method, a sol-gel method, an oxalic acid method, etc. may be used as the semiconductor particles. With the solid-phase synthesis method, the doping amount can be easily controlled, and any doping amount of particles can therefore be easily obtained. Moreover, highly crystalline particles can be obtained. With the hydrothermal synthesis method, the supercritical hydrothermal synthesis method, or the sol-gel method, highly crystalline nanosized particles can be obtained. The use of highly crystalline particles increases electrical resistance of the semiconductor-containing layer, and a dielectric breakdown of the semiconductor-containing layer is therefore less likely to occur. The use of nanosized particles can reduce the thickness of the semiconductor-containing layer. Reducing the thickness of the semiconductor-containing layer and thus the thickness of the dielectric layer can increase the volume energy density of the transducer, and can reduce an applied voltage and save power.

It is desirable that the semiconductor particles be present in a monodispersed state in the elastomer. If the semiconductor particles are present in an agglomerated state in the elastomer, insulation properties in the region where the semiconductor particles are agglomerated are degraded, which degrades the overall insulation properties of the semiconductor-containing layer. This reduces dielectric breakdown strength of the dielectric layer. In order to increase dispersibility of the semiconductor particles, the semiconductor particles may be subjected to a known surface treatment depending on the type of elastomer. In this case, it is desirable to use a surface treatment agent capable of binding covalently to both the semiconductor particles and the elastomer. Covalent bonding increases affinity between the semiconductor particles and the elastomer, whereby microvoids are less likely to be created, and the semiconductor particles are less likely to be separated from the elastomer. The semiconductor-containing layer therefore has increased dielectric breakdown strength. For example, the semiconductor particles synthesized by the sol-gel method have many hydroxyl groups at their surfaces. Accordingly, these semiconductor particles tend to bond covalently to the elastomer even if they are not subjected to a surface treatment. The semiconductor particles synthesized by the sol-gel method are therefore preferred to increase the dielectric breakdown strength of the semiconductor-containing layer.

Particles having high carrier density are preferred as the semiconductor particles. The use of the semiconductor particles having high carrier density can increase the charge density in the semiconductor-containing layer even if only a small amount of semiconductor particles is mixed with the elastomer. Mixing a small amount of semiconductor particles with the elastomer improves flexibility of the semiconductor-containing layer. Mixing a small amount of semiconductor particles with the elastomer can also suppress hopping between the particles upon voltage application as the distance between the semiconductor particles in the elastomer is increased. This reduces a leakage current, and a dielectric breakdown of the semiconductor-containing layer is less likely to occur. Increasing the amount of semiconductor particles to be mixed with the elastomer can increase the charge density in the semiconductor-containing layer, but may reduce flexibility and resistance to dielectric breakdown. The amount of semiconductor particles to be mixed with the elastomer is therefore determined, in view of the conflicting advantages, as appropriate so that the semiconductor-containing layer has a desired dielectric constant, volume resistivity, flexibility, etc. For example, the amount of semiconductor particles is in the range of 1 part by mass to 120 parts by mass, both inclusive, per 100 parts by mass of the elastomer. The amount of semiconductor particles is more preferably in the range of 5 parts by mass to 80 parts by mass, both inclusive.

The shape of the semiconductor particles is not particularly limited. For example, in the case where the semiconductor particles have a low aspect ratio, the semiconductor particles are less likely to contact each other even if a large amount of semiconductor particles is mixed with the elastomer. The semiconductor particles having a low aspect ratio is therefore effective in suppressing hopping between the particles upon voltage application. On the other hand, in the case where the semiconductor particles have a high aspect ratio, there is a possibility that the charge density may be increased even if only a small amount of semiconductor particles is mixed with the elastomer.

In the flexible transducer, the thickness of the dielectric layer affects the relationship between the applied voltage and the generated force. That is, reducing the thickness of the dielectric layer can reduce the applied voltage per unit thickness. It is therefore more desirable for the dielectric layer to have a smaller thickness. That is, it is more desirable for the semiconductor-containing layer to have a smaller thickness. The size of the semiconductor particles is determined as appropriate based on the thickness of the semiconductor-containing layer. For example, in the case where the semiconductor-containing layer has a thickness of about 20 the particle size of the semiconductor particles (the particle size of primary particles, not agglomerates) is desirably 500 nm or less, and more preferably 100 nm or less, and more preferably 50 nm or less.

The semiconductor-containing layer need only contain at least one of an inorganic semiconductor and an organic semiconductor. It is desirable to use polyaniline, polythiophene, etc. as the organic semiconductor. The semiconductor-containing layer containing inorganic semiconductor particles is desirable in order to increase the carrier concentration and because impurities are less likely to enter the semiconductor-containing layer. In order to increase the dielectric breakdown strength of the semiconductor-containing layer, the volume resistivity of the semiconductor-containing layer is desirably 10¹⁰ Ω·cm or more. The volume resistivity of the semiconductor-containing layer is preferably 10¹² Ω·cm.

The semiconductor-containing layer may further contain insulating particles in addition to the semiconductor. Adding the insulating particles can increase the volume resistivity of the semiconductor-containing layer and can increase the dielectric breakdown strength of the semiconductor-containing layer. For example, powder of silica, titanium oxide, barium titanate, calcium carbonate, clay, burnt clay, talc, etc. is used as the insulating particles. Either one kind of such powder or a mixture of more than one kind of such powder can be used as the insulating particles. Silica, titanium oxide, and barium titanate which are produced by a hydrolysis reaction of an organometallic compound (sol-gel method) may be used. For example, barium titanate has a large dielectric constant. Adding dielectric particles such as barium titanate to the semiconductor-containing layer can therefore increase electrostatic attraction that occurs upon voltage application. The semiconductor-containing layer can contain a crosslinking agent, a reinforcing agent, a plasticizer, an anti-aging agent, a coloring agent, etc. in addition to the insulating particles.

[High Resistance Layer]

As shown in the third and fourth embodiments, it is desirable that the dielectric layer include a high resistance layer containing an elastomer and having volume resistivity of 10¹² Ω·cm or more. The high resistance layer may be formed of only the elastomer, or may contain the elastomer and other component.

Preferred examples of the elastomer include an ethylene-propylene-diene copolymer (EPDM), isoprene rubber, natural rubber, fluororubber, nitrile rubber (NBR), hydrogenated nitrile rubber (H-NBR), silicone rubber, urethane rubber, acrylic rubber, butyl rubber, styrene butadiene rubber, an ethylene-vinyl acetate copolymer, and an ethylene-vinyl acetate-acrylic acid ester copolymer. An elastomer modified by introducing functional groups therein etc. may be used such as epoxidized natural rubber or carboxyl group-modified hydrogenated nitrile rubber (XH-NBR). Either one kind of elastomer or a mixture of more than one kind of elastomer may be used as the elastomer.

One of other components that are contained in addition to the elastomer is insulating particles. Adding the insulating particles can increase the volume resistivity of the high resistance layer. For example, powder of silica, titanium oxide, barium titanate, calcium carbonate, clay, burnt clay, talc, etc. is used as the insulating particles. Either one kind of such powder or a mixture of more than one kind of such powder can be used as the insulating particles. As in the case of the semiconductor-containing layer, silica, titanium oxide, and barium titanate which are produced by a sol-gel method may be used.

In order to block the flow of electrons to further enhance insulation properties, it is desirable that the elastomer be chemically bonded to the insulating particles. For this purpose, it is desirable that both the elastomer and the insulating particles have functional groups that can react with each other. Examples of the functional groups include a hydroxyl group (—OH), a carboxyl group (—COOH), and a maleic anhydride group. In this case, an elastomer modified by introducing functional groups therein etc., such as carboxyl group-modified hydrogenated nitrile rubber, is preferred as the elastomer. In the case of the insulating particles, functional groups can be introduced into the insulating particles or the number of functional groups in the insulating particles can be increased by a production method or by performing a surface treatment after production of the insulating particles. The larger the number of functional groups is, the more the reactivity between the elastomer and the insulating particles improves.

The amount of insulating particles to be mixed with the elastomer is determined in view of the volume resistivity of the elastomer etc. For example, it is desirable that the amount of insulating particles be in the range of 5 parts by mass to 50 parts by mass, both inclusive, per 100 parts by mass of the elastomer. Less than 5 parts by mass of the insulating particles are not very effective in increasing electrical resistance, and more than 50 parts by mass of the insulating particles harden the high resistance layer and may degrade flexibility thereof.

A manufacturing method of the dielectric layer will be described below. In the case where the dielectric layer is a single layer (semiconductor-containing layer), the semiconductor-containing layer can be manufactured by, e.g., coating a base material with a raw material solution containing a raw material such as a polymer corresponding to the elastomer content and a semiconductor and drying the coating film (by causing a crosslinking reaction as necessary). In the case where the dielectric layer is a stack of two or more layers, each layer is first formed by coating a base material with a raw material solution and drying the coating film (by causing a crosslinking reaction as necessary). Next, the layers thus formed are stacked on each other, and the base materials are delaminated, whereby the stack can be manufactured.

<Electrode>

In the flexible transducer of the present invention, the pair of electrodes contain a binder and a conductive material. A resin or an elastomer can be used as the binder. The elastomer is preferred as the binder because the elastomer can form an electrode whose electrical resistance is less likely to increase even if it is extended or contracted. Examples of the elastomer include crosslinked rubbers such as silicone rubber, NBR, EPDM, natural rubber, styrene-butadiene rubber (SBR), acrylic rubber, urethane rubber, epichlorohydrin rubber, chlorosulfonated polyethylene, and chlorinated polyethylene, and thermoplastic elastomers such a styrene elastomer, an olefin elastomer, a vinyl chloride elastomer, a polyester elastomer, a polyurethane elastomer, and a polyamide elastomer. An elastomer modified by introducing functional groups therein etc. may be used such as epoxy group-modified acrylic rubber or carboxyl group-modified hydrogenated nitrile rubber.

The type of conductive material is not particularly limited. The conductive material can be selected as appropriate from conductive carbon powder such as carbon black, carbon nanotube, and graphite, metal powder such as silver, gold, copper, nickel, rhodium, palladium, chromium, titanium, platinum, iron, and alloys thereof, etc. Powder composed of metal-coated particles may be used such as silver-coated copper powder. One kind of such a material or a mixture of more than one kind of such a material is used.

For example, in the case where the particles to be coated with a metal are particles other than a metal, specific gravity of the conductive material can be reduced as compared to the case where the particles are composed of only a metal. Accordingly, when the conductive material is used for a coating material, settling of the conductive material is suppressed, and dispersibility thereof is improved. Moreover, conductive materials with various shapes can be easily manufactured by processing the particles. Cost for the conductive material can also be reduced. The metal materials listed above, such as silver, are used as the metal for coating the particles. A carbon material such as carbon black, calcium carbonate, a metal oxide such as titanium dioxide, aluminum oxide, or barium titanate, an inorganic substance such as silica, a resin such as acrylic or urethane, etc. is used as the particles other than a metal.

The electrodes may further contain, as necessary, an additive such as a crosslinking agent, a dispersing agent, a reinforcing agent, a plasticizer, an anti-aging agent, or a coloring agent in addition to the binder and the conductive material. For example, in the case of using an elastomer as the binder, a conductive coating material can be prepared by adding the conductive material and, as necessary, the additive to a polymer solution of a polymer corresponding to the elastomer content in a solvent, and stirring and mixing the resultant solution. The electrodes are formed by directly coating two opposite surfaces of the dielectric layer with the conductive coating material thus prepared. Alternatively, a release film may be coated with the conductive coating material to form electrodes, and the electrodes thus formed may be transferred to the two opposite surfaces of the dielectric layer.

Various known methods can be used as a coating method for the conductive coating material. Examples of the coating method include a dip method, a spray method, a bar coating method, etc. in addition to printing methods such as inkjet printing, flexographic printing, gravure printing, screen printing, pad printing, and lithography. For example, the use of the printing methods is advantageous in that a coated area and a non-coated area can be separately formed easily. The use of the printing methods is also advantageous in that printing of large areas, thin lines, and complicated shapes can be easily performed. Among the printing methods, the screen printing method is preferred because a high-viscosity coating material can be used and the thickness of a coating film can be easily adjusted.

Embodiments of a speaker, a power generating element, and a capacitive sensor will be described below as embodiments of the flexible transducer of the present invention.

### Fifth Embodiment

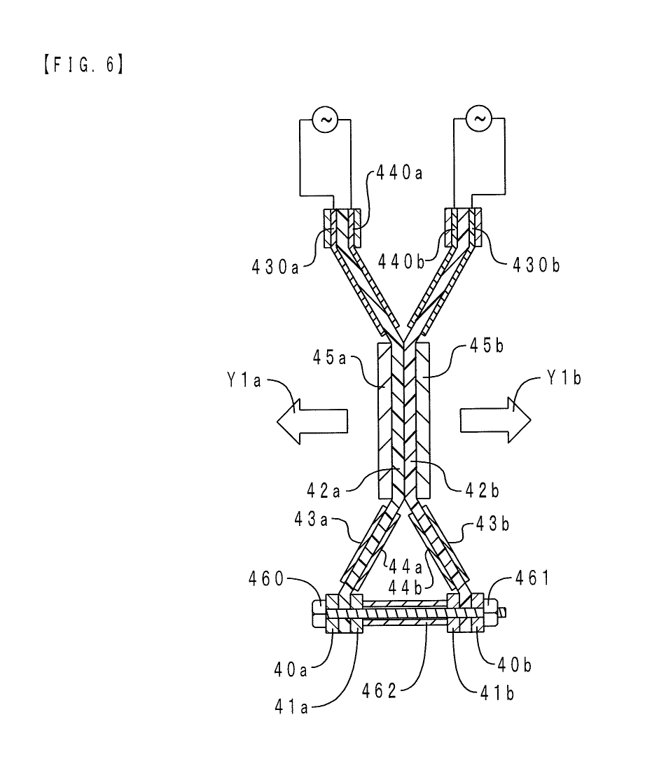

First, the configuration of a speaker according to the present embodiment will be described. FIG. 5 is a perspective view of the speaker of the present embodiment. FIG. 6 is a sectional view taken along line VI-VI in FIG. 5. As shown in FIGS. 5 and 6, a speaker 4 includes a first outer frame 40a, a first inner frame 41a, a first dielectric layer 42a, a first outer electrode 43a, a first inner electrode 44a, a first diaphragm 45a, a second outer frame 40b, a second inner frame 41b, a second dielectric layer 42b, a second outer electrode 43b, a second inner electrode 44b, a second diaphragm 45b, eight bolts 460, eight nuts 461, and eight spacers 462.

Each of the first outer frame 40a and the first inner frame 41a is made of a resin and has a ring shape. The first dielectric layer 42a has the shape of a circular thin film. The first dielectric layer 42a is formed of the same n-type semiconductor-containing layer as that of the first embodiment, which contains nitrile rubber and n-type semiconductor inorganic particles. The first dielectric layer 42a is stretched between the first outer frame 40a and the first inner frame 41a. That is, the first dielectric layer 42a is fixedly held under predetermined tension between the first outer frame 40a on the front side and the first inner frame 41a on the back side. The first diaphragm 45a is made of a resin and has a disc shape. The first diaphragm 45a has a smaller diameter than the first dielectric layer 42a. The first diaphragm 45a is disposed substantially in the center of the front surface of the first dielectric layer 42a.

The first outer electrode 43a has a ring shape. The first outer electrode 43a is affixed to the front surface of the first dielectric layer 42a. The first inner electrode 44a also has a ring shape. The first inner electrode 44a is affixed to the back surface of the first dielectric layer 42a. The first outer electrode 43a and the first inner electrode 44a have their back surfaces facing each other in the front-back direction with the first dielectric layer 42a interposed therebetween. Both the first outer electrode 43a and the first inner electrode 44a contain acrylic rubber and carbon black. As shown in FIG. 6, the first outer electrode 43a includes a terminal 430a. The first inner electrode 44a includes a terminal 440a. A voltage is externally applied to the terminals 430a, 440a.

The second outer frame 40b, the second inner frame 41b, the second dielectric layer 42b, the second outer electrode 43b, the second inner electrode 44b, and the second diaphragm 45b (hereinafter these members will be collectively referred to as the “second members”) are similar in configuration, material, and shape to the first outer frame 40a, the first inner frame 41a, the first dielectric layer 42a, the first outer electrode 43a, the first inner electrode 44a, and the first diaphragm 45a (hereafter these members will be collectively referred to as the “first members”). Arrangement of the second members is symmetrical to that of the first members in the front-back direction. To explain it briefly, the second dielectric layer 42b is formed of an n-type semiconductor-containing layer and is stretched between the second outer frame 40b and the second inner frame 41b. The second diaphragm 45b is disposed substantially in the center of the front surface of the second dielectric layer 42b. The second outer electrode 43b is printed on the front surface of the second dielectric layer 42b. The second inner electrode 44b is printed on the back surface of the second dielectric layer 42b. Both the second outer electrode 43b and the second inner electrode 44b contain acrylic rubber and carbon black. A voltage is externally applied to a terminal 430b of the second outer electrode 43b and a terminal 440b of the second inner electrode 44b.

The first members and the second members are fixed together via the eight spacers 462 with the eight bolts 460 and the eight nuts 461. The sets of “bolt 460, nut 461, and spacer 462” are arranged at predetermined intervals in the circumferential direction of the speaker 4. The bolts 460 extend from the front surface of the first outer frame 40a and beyond the front surface of the second outer frame 40b. The nuts 461 are screwed on the penetrating ends of the bolts 460. The spacers 462 are made of a resin and are attached around the shanks of the bolts 460. The spacers 462 secure a predetermined interval between the first inner frame 41a and the second inner frame 41b. The back surface of the central portion of the first dielectric layer 42a (the back side of the portion on which the first diaphragm 45a is disposed) is bonded to the back surface of the central portion of the second dielectric layer 42b (the back side of the portion on which the second diaphragm 45b is disposed). Accordingly, a biasing force in the direction shown by a white arrow Y1a in FIG. 6 is accumulated in the first dielectric layer 42a, and a biasing force in the direction shown by a white arrow Y1b in FIG. 6 is accumulated in the second dielectric layer 42b.

Next, operation of the speaker 4 will be described. In an initial state (offset state), a predetermined voltage (offset voltage) is applied to the first outer electrode 43a and the first inner electrode 44a and to the second outer electrode 43b and the second inner electrode 44b via the terminals 430a, 440a and the terminals 430b, 440b. When the speaker 4 is in operation, voltages of opposite phases are applied to the terminals 430a, 440a and the terminals 430b, 440b. For example, if an offset voltage of +1 V is applied to the terminals 430a, 440a, a part of the first dielectric layer 42a which is located between the first outer electrode 43a and the first inner electrode 44a is reduced in thickness, and also is extended in the radial direction. At the same time, a voltage of an opposite phase (offset voltage of −1 V) is applied to the terminals 430b, 440b. A part of the second dielectric layer 42b which is located between the second outer electrode 43b and the second inner electrode 44b is thus increased in thickness and also is contracted in the radial direction. The second dielectric layer 42b is thus elastically deformed in the direction shown by the white arrow Y1b in FIG. 6 by its own biasing force while pulling the first dielectric layer 42a. On the other hand, if an offset voltage of +1 V is applied to the terminals 430b, 440b and a voltage of an opposite phase (offset voltage of −1 V) is applied to the terminals 430a, 440a, the first dielectric layer 42a is elastically deformed in the direction shown by the white arrow Y1a in FIG. 6 by its own biasing force while pulling the second dielectric layer 42b. The first diaphragm 45a and the second diaphragm 45b are thus vibrated to vibrate air, thereby producing sound.

Functions and effects of the speaker 4 will be described below. According to the present embodiment, each of the first dielectric layer 42a and the second dielectric layer 42b has a large dielectric constant and high dielectric breakdown strength. Moreover, the present embodiment has the effect of increasing the dielectric constant by polarization of the n-type semiconductor inorganic particles even if the applied voltage has a high frequency. The first outer electrode 43a, the first inner electrode 44a, the second outer electrode 43b, and the second inner electrode 44b (hereinafter referred to as the “electrodes 43a, 44a, 43b, 44b”) are flexible and are capable of extending and contracting. Accordingly, the entire speaker 4 is flexible and movement of the first dielectric layer 42a and the second dielectric layer 42b is less likely to be restricted by the electrodes 43a, 44a, 43b, 44b. The speaker 4 therefore has excellent durability and responsiveness. In particular, the speaker 4 has satisfactory responsiveness in a high frequency region.

### Sixth Embodiment

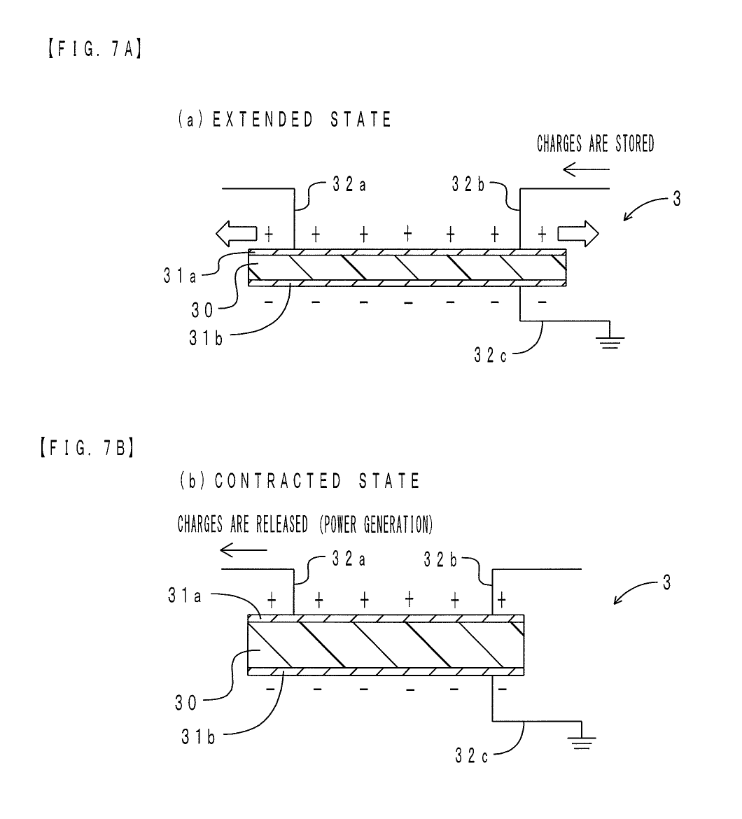

First, the configuration of a power generating element according to the present embodiment will be described. FIGS. 7A and 7B show schematic sectional views of the power generating element of the present embodiment. FIG. 7A shows an extended state, and FIG. 7B shows a contracted state.

As shown in FIGS. 7A and 7B, a power generating element 3 includes a dielectric layer 30, electrodes 31a, 31b, and wires 32a to 32c. The dielectric layer 30 is formed of the same n-type semiconductor-containing layer as that of the first embodiment, which contains nitrile rubber and n-type semiconductor inorganic particles. The electrode 31a is disposed so as to cover substantially the entire upper surface of the dielectric layer 30. Similarly, the electrode 31b is disposed so as to cover substantially the entire lower surface of the dielectric layer 30. The wires 32a, 32b are connected to the electrode 31a. That is, the electrode 31a is connected to an external load (not shown) via the wire 32a. The electrode 31a is also connected to a power supply (not shown) via the wire 32b. The electrode 31b is grounded by the wire 32c. Both of the electrodes 31a, 31b contain acrylic rubber and carbon black.

Next, operation of the power generating element 3 will be described. If the power generating element 3 is compressed and the dielectric layer 30 is extended in a direction parallel to the faces of the electrodes 31a, 31b as shown by white arrows in FIG. 7A, the dielectric layer 30 is reduced in thickness, and electric charges are accumulated between the electrodes 31a, 31b. If the compressive force is removed thereafter, the dielectric layer 30 is contracted due to its elastic restoring force and is increased in thickness, as shown in FIG. 7B. At this time, the accumulated electric charges are discharged through the wire 32a.

Next, functions and effects of the power generating element 3 will be described. According to the present embodiment, the dielectric layer 30 has a large dielectric constant and high dielectric breakdown strength. The power generating element 3 can therefore store many electric charges between the electrodes 31a, 31b and has excellent durability. The electrodes 31a, 31b are flexible and are capable of extending and contracting. Accordingly, the entire power generating element 3 is flexible, and movement of the dielectric layer 30 is less likely to be restricted by the electrodes 31a, 31b.

### Seventh Embodiment

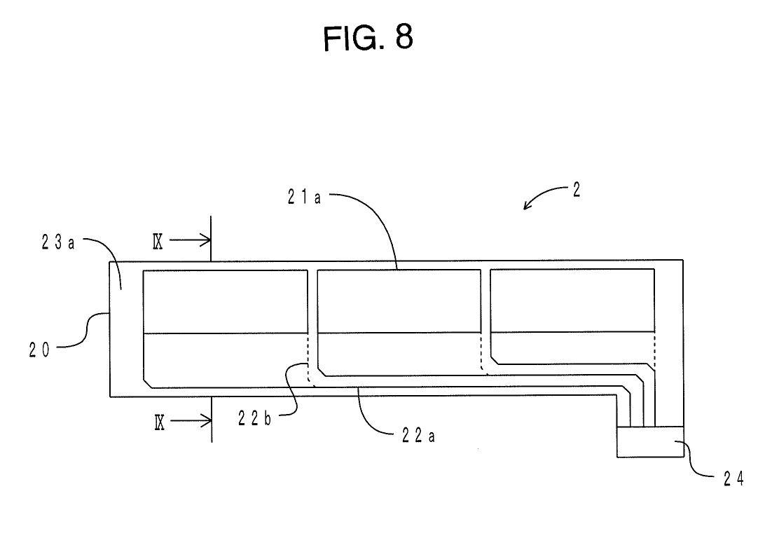

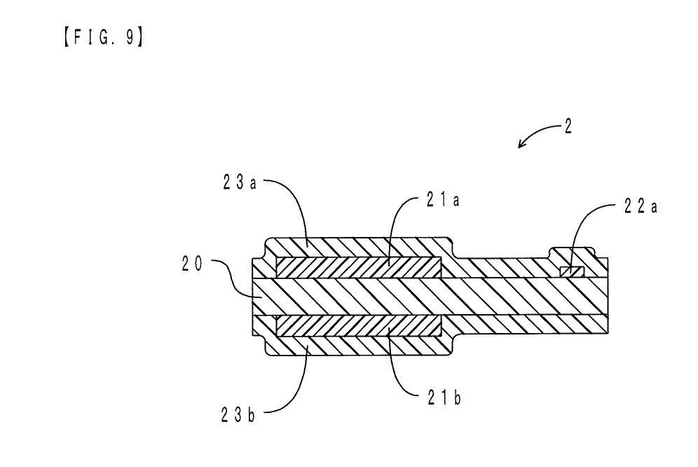

First, the configuration of a capacitive sensor according to the present embodiment will be described. FIG. 8 is a top view of the capacitive sensor. FIG. 9 is a sectional view taken along line IX-IX in FIG. 8. As shown in FIGS. 8 and 9, a capacitive sensor 2 includes a dielectric layer 20, a pair of electrodes 21a, 21b, wires 22a, 22b, and cover films 23a, 23b.

The dielectric layer 20 has a strip shape extending in the right-left direction. The dielectric layer 20 has a thickness of about 300 μm. The dielectric layer 20 is formed of the same n-type semiconductor-containing layer as that of the first embodiment, which contains nitrile rubber and n-type semiconductor inorganic particles.

The electrode 21a has a rectangular shape. Three electrodes 21a are formed on the upper surface of the dielectric layer 20 by screen printing. Similarly, the electrode 21b has a rectangular shape. Three electrodes 21b are formed on the lower surface of the dielectric layer 20 so as to face the electrodes 21a with the dielectric layer 20 interposed therebetween. The electrodes 21b are screen-printed on the lower surface of the dielectric layer 20. The three pairs of electrodes 21a, 21b are thus disposed with the dielectric layer 20 interposed therebetween. The electrodes 21a, 21b contain acrylic rubber and carbon black.

Each of the wires 22a is connected to a corresponding one of the electrodes 21a formed on the upper surface of the dielectric layer 20. The electrodes 21a are connected to a connector 24 by the wires 22a. The wires 22a are formed on the upper surface of the dielectric layer 20 by screen printing. Similarly, each of the wires 22b is connected to a corresponding one of the electrodes 21b formed on the lower surface of the dielectric layer 20 (shown by dotted lines in FIG. 8). The electrodes 21b are connected to a connector (not shown) by the wires 22b. The wires 22b are formed on the lower surface of the dielectric layer 20 by screen printing. The wires 22a, 22b contain acrylic rubber and silver powder.

The cover film 23a is made of acrylic rubber and has a strip shape extending in the right-left direction. The cover film 23a covers the upper surfaces of the dielectric layer 20, the electrodes 21a, and the wires 22a. Similarly, the cover film 23b is made of acrylic rubber and has a strip shape extending in the right-left direction. The cover film 23b covers the lower surfaces of the dielectric layer 20, the electrodes 21b, and the wires 22b.

Next, operation of the capacitive sensor 2 will be described. For example, if the capacitive sensor 2 is pressed from above, the dielectric layer 20, the electrode 21a, and the cover film 23a are together curved downward. The dielectric layer 20 is thus compressed and reduced in thickness. As a result, capacitance between the electrodes 21a, 21b is increased. Compressive deformation is detected by this change in capacitance.

Functions and effects of the capacitive sensor 2 will be described below. According to the present embodiment, the dielectric layer 20 has a large dielectric constant and high dielectric breakdown strength. The dielectric layer 20 therefore has large capacitance, and even a small amount of displacement can be detected with high sensitivity. The capacitive sensor 2 has excellent durability. The electrodes 21a, 21b and the wires 22a, 22b are flexible and are capable of extending and contracting. Accordingly, the entire capacitive sensor 2 is flexible, and movement of the dielectric layer 20 is less likely to be restricted by the electrodes 21a, 21b. In the capacitive sensor 2, the three pairs of electrodes 21a, 21b are formed so as to face each other with the dielectric layer 20 interposed therebetween. However, the number, size, shape, arrangement, etc. of electrodes may be determined as appropriate according to the intended use.

### EXAMPLES

The present invention will be described in more detail based on examples.

### Manufacturing of Semiconductor-Containing Layer

### Example 1

A semiconductor-containing layer was manufactured by using n-type inorganic semiconductor powder. Phosphorus (P)-doped tin oxide (SnO₂) powder (“EPSP2” made by Mitsubishi Material Corporation) was used as the n-type inorganic semiconductor powder. First, a polymer of carboxyl group-modified hydrogenated nitrile rubber (“Therban (registered trademark) XT8889” made by LANXESS) was dissolved in acetylacetone to prepare a polymer solution having a solid content concentration of 12 mass %. N-type inorganic semiconductor powder was dispersed in acetylacetone to prepare a dispersed solution having a concentration of 12 mass %. Next, 13 parts by mass of the dispersed solution of the inorganic semiconductor powder was mixed with 100 parts by mass of the polymer solution to prepare a mixed solution. Moreover, 5 parts by mass of an acetylacetone solution of tetrakis (2-ethylhexyloxy) titanium (concentration of 20 mass %) was added as a crosslinking agent to the mixed solution thus prepared. A base material was coated with the mixed solution and dried, and then heated at 150° C. for 60 minutes, whereby an n-type semiconductor-containing layer was manufactured. The n-type semiconductor-containing layer thus manufactured had a thickness of about 20 μm. This n-type semiconductor-containing layer is referred to as the semiconductor-containing layer of Example 1.

### Example 2

An n-type semiconductor-containing layer was manufactured in a manner similar to that of Example 1 except that the amount of dispersed solution of n-type inorganic semiconductor powder was changed to 52 parts by mass. The n-type semiconductor-containing layer thus manufactured is referred to as the semiconductor-containing layer of Example 2.

### Example 3

An n-type semiconductor-containing layer was manufactured in a manner similar to that of Example 2 except that barium titanate (BaTiO₃) powder was mixed as insulating particles. The barium titanate powder was manufactured as follows. First, 0.019 mol of diethoxybarium and 0.019 mol of tetraisopropyltitanium were dissolved in 116 ml of 2-methoxyethanol. Next, this solution was processed at 125° C. for three hours while being refluxed, and then was further processed at 70° C. for six hours while being refluxed. Barium titanate powder thus produced was added to a mixture of a polymer solution and a dispersed solution of inorganic semiconductor powder. The n-type semiconductor-containing layer thus manufactured is referred to as the semiconductor-containing layer of Example 3.

### Example 4

An n-type semiconductor-containing layer was manufactured in a manner similar to that of Example 1 except that the amount of dispersed solution of n-type inorganic semiconductor powder was changed to 100 parts by mass. The n-type semiconductor-containing layer thus manufactured is referred to as the semiconductor-containing layer of Example 4.

### Example 5

A semiconductor-containing layer was manufactured by using n-type inorganic semiconductor powder. Inorganic semiconductor powder composed of antimony (Sb)-doped tin oxide (SnO₂) and titanium oxide (TiO₂) (“ET300W” made by ISHIHARA SANGYO KAISHA, LTD.) was used as n-type inorganic semiconductor powder. First, a polymer of carboxyl group-modified hydrogenated nitrile rubber (“XER32” made by JSR Corporation) was dissolved in acetylacetone to prepare a polymer solution having a solid content concentration of 12 mass %. N-type inorganic semiconductor powder was dispersed in acetylacetone to prepare a dispersed solution having a concentration of 12 mass %. Next, 50 parts by mass of the dispersed solution of the inorganic semiconductor powder was mixed with 100 parts by mass of the polymer solution to prepare a mixed solution. Moreover, 5 parts by mass of an acetylacetone solution of tetrakis (2-ethylhexyloxy) titanium (concentration of 20 mass %) was added as a crosslinking agent to the mixed solution thus prepared. A base material was coated with the mixed solution and dried, and then heated at 150° C. for 60 minutes, whereby an n-type semiconductor-containing layer was manufactured. The n-type semiconductor-containing layer thus manufactured had a thickness of about 20 μm. This n-type semiconductor-containing layer is referred to as the semiconductor-containing layer of Example 5.

### Example 6

An n-type semiconductor-containing layer was manufactured in a manner similar to that of Example 1 except that the type and amount of n-type inorganic semiconductor powder were changed. That is, lanthanum (La)-doped barium titanate (BaTiO₃) powder manufactured as follows was used as n-type inorganic semiconductor powder, and 60 parts by mass of a dispersed solution of the n-type inorganic semiconductor powder was mixed. The n-type semiconductor-containing layer thus manufactured is referred to as the semiconductor-containing layer of Example 5.

First, diethoxybarium, tetraisopropyltitanium, and triisopropoxylanthanum were dissolved at a molar ratio of 0.995:1:0.005 in 116 ml of 2-methoxyethanol. In this case, 0.019 mol of diethoxybarium was dissolved. Next, the resultant solution was processed at 125° C. for three hours while being refluxed, and then was further processed at 70° C. for six hours while being refluxed. Barium titanate powder doped with 0.5 mol % of lanthanum was thus produced.

The synthesized barium titanate was measured with an X-ray diffractometer (XRD) (“EMPYREAN (registered trademark)” made by PANalytical B. V.), and it was verified that the barium titanate was highly crystalline barium titantate. An element ratio was measured with an inductively-coupled plasma (ICP) emission spectrophotometric analyzer (“Optima 4300DV” made by PerkinElmer Co., Ltd.), and it was verified that Ba:Ti:La=0.995:1:0.005.

### Example 7

An n-type semiconductor-containing layer was manufactured in a manner similar to that of Example 6 except that the ratio of diethoxybarium, tetraisopropyltitanium, and triisopropoxylanthanum was changed to 0.90:1:0.1 in manufacturing of lanthanum-doped barium titanate powder. The doping amount of lanthanum in the produced barium titanate powder was 10 mol %. The n-type semiconductor-containing layer thus manufactured is referred to as the semiconductor-containing layer of Example 7.

The synthesized barium titanate was measured with an XRD (same as above) and it was verified that the barium titanate was highly crystalline barium titantate. An element ratio was measured with an ICP emission spectrophotometric analyzer (same as above), and it was verified that Ba:Ti:La=0.9:1:0.1.

### Example 8

An n-type semiconductor-containing layer was manufactured in a manner similar to that of Example 7 except that no crosslinking agent was mixed. The n-type semiconductor-containing layer thus manufactured is referred to as the semiconductor-containing layer of Example 8.

### Example 9

An n-type semiconductor-containing layer was manufactured in a manner similar to that of Example 1 except that the type and amount of n-type inorganic semiconductor powder were changed. That is, niobium (Nb)-doped barium titanate (BaTiO₃) powder manufactured as follows was used as n-type inorganic semiconductor powder, and 60 parts by mass of a dispersed solution of the n-type inorganic semiconductor powder was mixed. The n-type semiconductor-containing layer thus manufactured is referred to as the semiconductor-containing layer of Example 9.

First, diethoxybarium, tetraisopropyltitanium, and pentaethoxyniobium were dissolved at a molar ratio of 0.95:1:0.05 in 116 ml of 2-methoxyethanol. In this case, 0.019 mol of diethoxybarium was dissolved. Next, the resultant solution was processed at 125° C. for three hours while being refluxed, and then was further processed at 70° C. for six hours while being refluxed. Barium titanate powder doped with 5 mol % of niobium was thus produced.

The synthesized barium titanate was measured with an XRD (same as above), and it was verified that the barium titanate was highly crystalline barium titantate. An element ratio was measured with an ICP emission spectrophotometric analyzer (same as above), and it was verified that Ba:Ti:Nb=0.95:1:0.05.

### Example 10

Niobium-doped titanium dioxide (TiO₂) powder was manufactured by using only tetraisopropyltitanium and pentaethoxyniobium in manufacturing of the niobium-doped barium titanate powder in Example 9 and changing the mixing ratio of tetraisopropyltitanium to pentaethoxyniobium to 0.95:0.05. An n-type semiconductor-containing layer was manufactured in a manner similar to that of Example 9 except for the use of this powder. The doping amount of niobium in titanium dioxide powder thus produced was 5 mol %. The n-type semiconductor-containing layer thus manufactured is referred to as the semiconductor-containing layer of Example 10.

The synthesized titanium dioxide was measured with an XRD (same as above), and it was verified that the titanium dioxide was highly crystalline titanium dioxide. An element ratio was measured with an ICP emission spectrophotometric analyzer (same as above), and it was verified that Ti:Nb=0.95:0.05.

### Example 11

A semiconductor-containing layer was manufactured by using polyaniline as a p-type organic semiconductor instead of n-type inorganic semiconductor powder. First, 1 mol (107 g) of o-toluidine was added to 1000 ml of 1 N hydrochloric acid to prepare an o-toluidine solution. 1 mol (228.21 g) of ammonium persulfate dissolved in 500 ml of 1 N hydrochloric acid was added as an oxidizing agent to the prepared o-toluidine solution, and the resultant solution was stirred at 15° C. for 10 hours to cause a polymerization reaction, whereby poly-o-toluidine was produced. Poly-o-toluidine thus produced was washed with methanol and water, and then added to a 0.1 N sodium hydroxide solution to cause a dedoping reaction. Poly-o-toluidine thus dedoped was washed again with methanol and water, and dissolved in tetrahydrofuran (THF). A polyester urethane resin having a sodium sulfonate group (VYLON (registered trademark) UR-5537″ made by TOYOBO CO., LTD.) was dissolved in THF to prepare a polymer solution. The polymer solution was mixed with the THF solution of poly-o-toluidine to prepare a mixed solution. Moreover, 5 parts by mass of “CORONATE (registered trademark) L” (made by Nippon Polyurethane Industry Co., Ltd., 75 mass % of ethyl acetate solution of modified tolylenediisocyanate) was added as a crosslinking agent to the prepared mixed solution. A base material was coated with the mixed solution and dried, whereby a p-type semiconductor-containing layer was manufactured. The semiconductor-containing layer thus manufactured had a thickness of about 20 μm. This p-type semiconductor-containing layer is referred to as the semiconductor-containing layer of Example 11.

<Physical Properties of Semiconductor-Containing Layer>

The dielectric constant, volume resistivity, and elastic modulus were measured for each of the semiconductor-containing layer of the examples. The measurement result is shown in Table 1 below. The measuring methods are as follows.

[Dielectric Constant]

The dielectric constant was measured by placing the semiconductor-containing layer in a sample holder (12962A made by Solatron) and by using a permittivity measurement interface (1296 made by Solatron) and a frequency response analyzer (1255B made by Solatron).

[Volume Resistivity]

The volume resistivity of the semiconductor-containing layer was measured according to JIS K6271 (2008). The measurement was performed by applying a DC voltage of 100 V.

[Elastic Modulus]

The static shear modulus of the semiconductor-containing layer was measured according to JIS K 6254 (2003). The percentage elongation in a low deformation tensile test was 25%.

<Manufacturing of Actuator>

Electrostrictive actuators were manufactured by using each of the semiconductor-containing layers of Examples 1 to 11 as a dielectric layer. An electrode was formed on both front and back surfaces of the dielectric layer by screen-printing a conductive coating material. The conductive coating material was prepared by mixing and dispersing carbon black in an acrylic rubber polymer solution. The generated force, displacement amount, and dielectric breakdown strength were measured for the actuators of Examples 1 to 11 thus manufactured. The actuators of Examples 1 to 11 are included in the flexible transducer of the present invention.

For comparison, four kinds of dielectric layers having no semiconductor-containing layer were manufactured, and the generated force, displacement amount, and dielectric breakdown strength were measured for actuators including these dielectric layers.

### Comparative Example 1

A dielectric layer was manufactured as follows. First, a polymer of carboxyl group-modified hydrogenated nitrile rubber (“Therban XT8889” made by LANXESS) was dissolved in acetylacetone to prepare a polymer solution having a solid content concentration of 12 mass %. Next, 5 parts by mass of an acetylacetone solution of tetrakis (2-ethylhexyloxy) titanium (concentration of 20 mass %) was added as a crosslinking agent to 100 parts by mass of the polymer solution. A base material was coated with the mixed solution and dried, and then heated at 150° C. for 60 minutes, whereby a dielectric layer was manufactured. The dielectric layer thus manufactured is referred to as the dielectric layer of Comparative Example 1, and an actuator including this dielectric layer is referred to as the actuator of Comparative Example 1.

### Comparative Example 2

A dielectric layer was manufactured in a manner similar to that of the dielectric layer of Comparative Example 1 except that TiO₂ powder (made by Sigma-Aldrich, mean particle size of 100 nm) was added as insulating particles. The dielectric layer thus manufactured is referred to as the dielectric layer of Comparative Example 2, and an actuator including this dielectric layer is referred to as the actuator of Comparative Example 2.

### Comparative Example 3

A dielectric layer was manufactured in a manner similar to that of the dielectric layer of Comparative Example 1 except that SiO₂ powder (made by Sigma-Aldrich, mean particle size of 100 nm) was added as insulating particles. The dielectric layer thus manufactured is referred to as the dielectric layer of Comparative Example 3, and an actuator including this dielectric layer is referred to as the actuator of Comparative Example 3.

### Comparative Example 4

First, a nitrile rubber film was manufactured from a polymer of carboxyl group-modified hydrogenated nitrile rubber (same as above) in a manner similar to that of Comparative Example 1. Next, the nitrile rubber film was immersed in a LiClO₄/propylene carbonate electrolytic solution for 24 hours to allow ion components (LiClO₄) of the electrolytic solution to permeate the nitrile rubber film. Then, the nitrile rubber film was dried at normal temperature for 24 hours in a vacuum oven. The nitrile rubber film impregnated with the ion components was thus manufactured as a dielectric layer. The dielectric layer thus manufactured is referred to as the dielectric layer of Comparative Example 4, and an actuator including this dielectric layer is referred to as the actuator of Comparative Example 4.

<Evaluation of Actuator>

[Measurement of Dielectric Breakdown Strength]

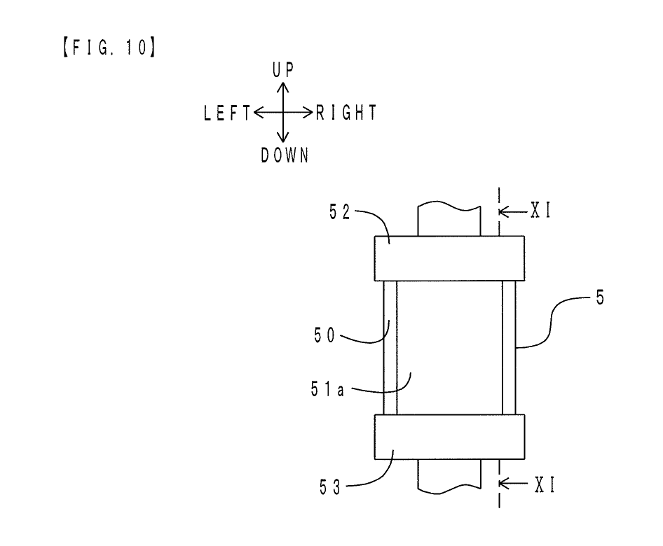

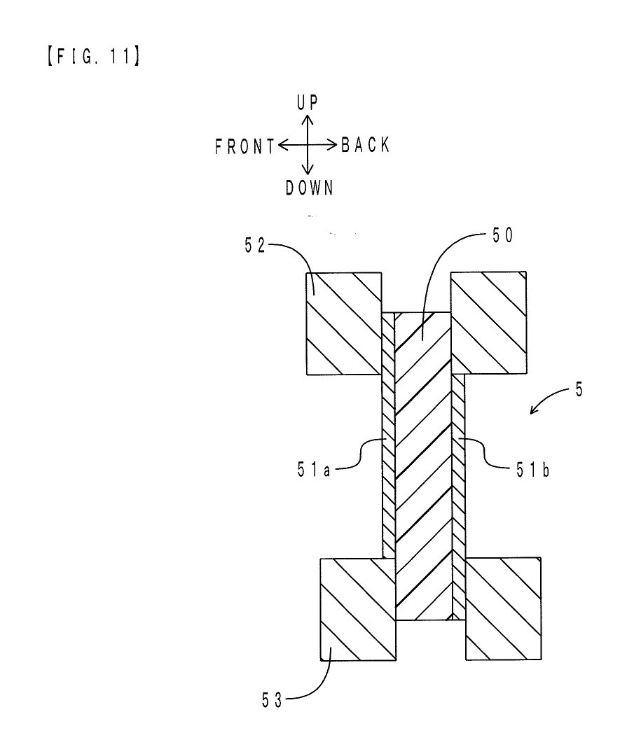

First, a measuring apparatus and a measuring method of the dielectric breakdown strength will be described. FIG. 10 is a front view showing the front side of an actuator attached to a measuring apparatus. FIG. 11 is a sectional view taken along line VI-VI in FIG. 10.

As shown in FIGS. 10 and 11, the upper end of an actuator 5 is held by an upper chuck 52 of the measuring apparatus. The lower end of the actuator 5 is held by a lower chuck 53. The actuator 5 is stretched in advance in the up-down direction and is attached in this stretched state between the upper chuck 52 and the lower chuck 53 (percentage elongation of 25%). A load cell (not shown) is disposed above the upper chuck 52.

The actuator 5 includes a dielectric layer 50 and a pair of electrodes 51a, 51b. The dielectric layer 50 has the shape of a 50 mm by 25 mm rectangular plate in a natural state. The configuration of the dielectric layer 50 varies from actuator to actuator (see Table 1 below). The electrodes 51a, 51b are disposed so as to face each other in the front-back direction with the dielectric layer 50 interposed therebetween. Each of the electrodes 51a, 51b has the shape of a 40 mm by 25 mm rectangular plate with a thickness of about 10 μM in a natural state. The electrodes 51a, 51b are arranged so as to be shifted from each other by 10 mm in the up-down direction. That is, the electrodes 51a, 51b overlap each other in the range of 30 mm by 25 mm with the dielectric layer 50 interposed therebetween. A wire (not shown) is connected to the lower end of the electrode 51a. Similarly, a wire (not shown) is connected to the upper end of the electrode 51b. The electrodes 51a, 51b are connected to a power source (not shown) via their corresponding wires. The electrode 51a on the front side serves as a positive electrode and the electrode 51b on the back side serves as a negative electrode when a voltage is applied.

Measurement of the dielectric breakdown strength was performed by increasing a voltage applied between the electrodes 51a, 51b in a stepwise manner, and was performed until a dielectric breakdown of the dielectric layer 50 occurred. The dielectric breakdown strength was calculated by dividing the voltage value immediately before the dielectric breakdown of the dielectric layer 50 by the overall thickness of the dielectric layer 50.

[Measurement of Generated Force]

Measurement of the generated force was performed by using the same apparatus as that used to measure the dielectric breakdown strength (see FIGS. 10 and 11). When a voltage is applied between the electrodes 51a, 51b, electrostatic attraction occurs between the electrodes 51a, 51b, and the dielectric layer 50 is compressed. The thickness of the dielectric layer 50 is thus reduced, and the dielectric layer 50 is extended in the stretching direction (up-down direction). As the dielectric layer 50 is extended, the stretching force in the up-down direction is reduced. The stretching force thus reduced upon voltage application was measured as the generated force by using the load cell. Measurement of the generated force was performed with field strength of 30 V/μm. The maximum generated force of the dielectric layer 50 was measured by increasing the applied voltage in a stepwise manner until just before the dielectric breakdown of the dielectric layer 50 occurred.

[Measurement of Displacement Amount]

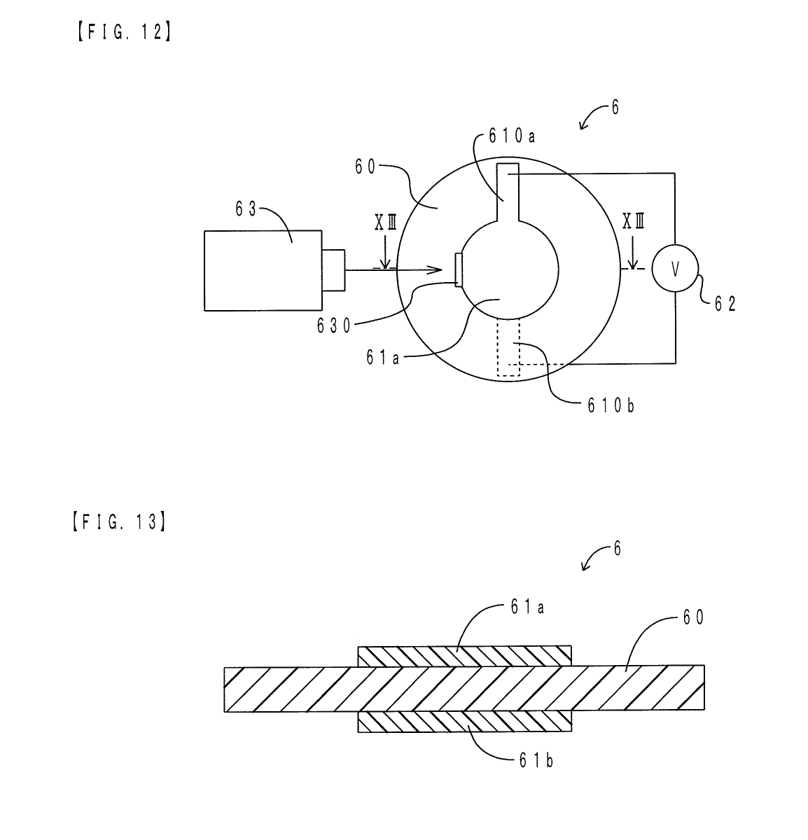

First, a measuring method of the displacement amount will be described. FIG. 12 is a top view of a manufactured actuator. FIG. 13 is a sectional view taken along line XIII-XIII in FIG. 12. As shown in FIGS. 12 and 13, an actuator 6 includes a dielectric layer 60 and a pair of electrodes 61a, 61b. The dielectric layer 60 has the shape of a circular thin film with a diameter of 70 mm. The dielectric layer 60 is biaxially stretched by 25% and is disposed in this stretched state. The configuration of the dielectric layer 60 varies from actuator to actuator (see Table 1 below). The pair of electrodes 61a, 61b are disposed so as to face each other in the up-down direction with the dielectric layer 60 interposed therebetween. Each of the electrodes 61a, 61b has the shape of a circular thin film with a diameter of about 27 mm, and is disposed substantially concentrically with the dielectric layer 60. A terminal portion 610a protruding radially outward is formed at the outer peripheral edge of the electrode 61a. The terminal portion 610a has the shape of a rectangular plate. Similarly, a terminal portion 610b protruding radially outward is formed at the outer peripheral edge of the electrode 61b. The terminal portion 610b has the shape of a rectangular plate. The terminal portion 610b is disposed at a position shifted by 180° from the terminal portion 610a in the circumferential direction of the electrodes 61a, 61b. Each of the terminal portions 610a, 610b is connected to a power supply 62 via a wire.

When a voltage is applied between the electrodes 61a, 61b, electrostatic attraction occurs between the electrodes 61a, 61b, and the dielectric layer 60 is compressed. The thickness of the dielectric layer 60 is thus reduced, and the dielectric layer 60 is extended radially outward. At this time, the electrodes 61a, 61b are also extended radially outward together with the dielectric layer 60. A marker 630 is attached in advance to the electrode 61a. Displacement of the marker 630 is measured as the displacement amount of the actuator 6 by using a displacement meter 63. Measurement of the displacement amount was performed with field strength of 30 V/μm. The maximum displacement amount of the dielectric layer 60 was measured by increasing the applied voltage in a stepwise manner until just before a dielectric breakdown of the dielectric layer 60 occurred. The displacement rate was calculated from the measured displacement amount, as given by the following expression (1).

Displacement Rate (%)=(displacement amount/electrode radius)×100 (1)

Table 1 shows the composition and physical properties of the dielectric layer in the actuator of each example and the measurement result of the generated force, displacement amount, and dielectric breakdown strength of the actuator of each example. Table 2 shows the composition and physical properties of the dielectric layer in the actuator of each comparative example and the measurement result of the generated force, displacement amount, and dielectric breakdown strength of the actuator of each example.

TABLE 1

| | | Example 1 | Example 2 | Example 3 | Example 4 | Example 5 | Example 6 |
|---|---|---|---|---|---|---|---|
| Polymer | XH—NBR | 100 | 100 | 100 | 100 | 100 | 100 |
| | Polyester | — | — | — | — | — | — |
| | Urethane Resin | | | | | | |
| Crosslinking | TOT *¹ | 5 | 5 | 5 | 5 | 5 | 5 |
| agent | CORONATE L | — | — | — | — | — | — |
| n-type | P—SnO₂ | 13 | 52 | 52 | 100 | — | — |
| inorganic | Sb—SnO₂,TiO₂ | — | — | — | — | 50 | — |
| semiconductor | La (0.5%)-BaTiO₃ | — | — | — | — | — | 60 |
| powder | La (10%)-BaTiO₃ | — | — | — | — | — | — |
| | Nb (5%)-BaTiO₃ | — | — | — | — | — | — |
| | Nb (5%)-TiO₂ | — | — | — | — | — | — |
| p-type organic semiconductor: | | — | — | — | — | — | — |
| polyaniline | | | | | | | |
| Insulating | TiO₂ | — | — | — | — | — | — |
| particles | BaTiO₃ | — | — | 6.6 | — | — | — |
| | SnO₂ | — | — | — | — | — | — |
| Ion | LiClO₄ | — | — | — | — | — | — |
| components | | | | | | | |
| Dielectric | 10000 Hz | 14.9 | 24.4 | 18.5 | 52.3 | 17.3 | 12.8 |
| constant | 100 Hz | 19.0 | 32.6 | 30.5 | 505.9 | 25.6 | 17.9 |
| | 1 Hz | 29.1 | 43.0 | 41.4 | 1248.2 | 30.6 | 28.1 |
| Volume resistivity [Ω · cm] | | 5.1 × 10¹¹ | 2.1 × 10¹³ | 1.0 × 10¹¹ | 4.0 × 10¹¹ | 2.1 × 10¹³ | 2.5 × 10¹² |
| Elastic modulus [MPa] | | 3.2 | 4.4 | 9.8 | 9.9 | 4.4 | 7.1 |
| Generated force [MPa] | | 0.19 | 0.28 | 0.28 | 0.38 | 0.20 | 0.18 |
| Maximum generated force [MPa] | | 0.81 | 1.20 | 2.00 | 1.65 | 1.35 | 0.79 |
| Displacement rate [%] | | 3.0 | 3.2 | 1.4 | 1.9 | 2.3 | 1.3 |
| Maximum displacement rate [%] | | 12.7 | 13.6 | 10.2 | 8.3 | 15.3 | 5.6 |
| Breakdown strength [V/μm] | | 65 | 70 | 90 | 55 | 80 | 65 |
| | | | Example 7 | Example 8 | Example 9 | Example 10 | Example 11 |
| | Polymer | XH—NBR | 100 | 100 | 100 | 100 | — |
| | | Polyester | — | — | — | — | 100 |
| | | Urethane Resin | | | | | |
| | Crosslinking | TOT *¹ | 5 | — | 5 | 5 | — |
| | agent | CORONATE L | — | — | — | — | 5 |
| | n-type | P—SnO₂ | — | — | — | — | — |
| | inorganic | Sb—SnO₂,TiO₂ | — | — | — | — | — |
| | semiconductor | La (0.5%)-BaTiO₃ | — | — | — | — | — |
| | powder | La (10%)-BaTiO₃ | 60 | 60 | — | — | — |
| | | Nb (5%)-BaTiO₃ | — | — | 60 | — | — |
| | | Nb (5%)-TiO₂ | — | — | — | 60 | — |
| | p-type organic semiconductor: | | — | — | — | — | 42.9 |
| | polyaniline | | | | | | |
| | Insulating | TiO₂ | — | — | — | — | — |
| | particles | BaTiO₃ | — | — | — | — | — |
| | | SnO₂ | — | — | — | — | — |
| | Ion | LiClO₄ | — | — | — | — | — |
| | components | | | | | | |
| | Dielectric | 10000 Hz | 20.7 | 20.1 | 18.3 | 15.2 | — |
| | constant | 100 Hz | 43.7 | 43.4 | 40.6 | 35.8 | 93 |
| | | 1 Hz | 48.9 | 49.8 | 45.2 | 39.8 | — |
| | Volume resistivity [Ω · cm] | | 3.1 × 10¹² | 9.0 × 10¹¹ | 1.0 × 10¹³ | 8.5 × 10¹² | 2.0 × 10¹⁰ |
| | Elastic modulus [MPa] | | 8.6 | 6.9 | 10.3 | 11.2 | 45 |
| | Generated force [MPa] | | 0.32 | 0.24 | 0.26 | 0.30 | 0.21 |
| | Maximum generated force [MPa] | | 1.85 | 1.58 | 1.92 | 1.65 | 0.89 |
| | Displacement rate [%] | | 1.9 | 1.7 | 1.3 | 1.3 | 0.2 |
| | Maximum displacement rate [%] | | 10.8 | 11.4 | 9.3 | 7.4 | 1.0 |
| | Breakdown strength [V/μm] | | 70 | 60 | 85 | 70 | 60 |

*¹ TOT: tetrakis (2-ethylhexyloxy) titanium

TABLE 2

| | | Comparative | Comparative | Comparative | Comparative |
|---|---|---|---|---|---|
| | | Example 1 | Example 2 | Example 3 | Example 4 |
| Polymer | XH-NBR | 100 | 100 | 100 | 100 |
| | Polyester | — | — | — | — |
| | Urethane Resin | | | | |
| Crosslinking | TOT *¹ | 5 | — | 5 | — |
| agent | CORONATE L | — | — | — | — |
| n-type | P—SnO₂ | — | — | — | — |
| inorganic | Sb—SnO₂, TiO₂ | — | — | — | — |
| semiconductor | La(0.5%)—BaTiO₃ | — | — | — | — |
| powder | La(10%)—BaTiO₃ | — | — | — | — |
| | Nb(5%)—BaTiO₃ | — | — | — | — |
| | Nb(5%)—TiO₂ | — | — | — | — |
| p-type organic semiconductor: | | — | — | — | — |
| polyaniline | | | | | |
| Insulating | TiO₂ | — | 60 | — | — |
| particles | BaTiO₃ | — | — | — | — |
| | SnO₂ | — | — | 60 | — |
| Ion | LiClO₄ | — | — | — | ◯ |
| components | | | | | |
| Dielectric | 10000 Hz | 11.9 | 11.8 | 12.1 | 12.0 |
| constant | 100 Hz | 13.5 | 13.5 | 13.8 | 13.8 |
| | 1 Hz | 15.2 | 15.2 | 15.9 | 4800.0 |

| | | | | |
|---|---|---|---|---|
| Volume resistivity [Ω · cm] | 2.0 × 10¹¹ | 8.0 × 10¹³ | 1.1 × 10¹² | 1.0 × 10⁹ |
| Elastic modulus [MPa] | 3.0 | 12.4 | 8.9 | 3.2 |
| Generated force [MPa] | 0.09 | 0.09 | 0.09 | — |
| Maximum generated force [MPa] | 0.24 | 0.60 | 0.50 | 0.20 |
| Displacement rate [%] | 1.5 | 0.4 | 0.5 | — |
| Maximum displacement rate [%] | 4.0 | 2.4 | 2.8 | 3.1 |
| Breakdown strength [V/μm] | 50 | 75 | 70 | 20 |

*¹ TOT: tetrakis (2-ethylhexyloxy) titanium

As shown in Table 1, the dielectric layers (semiconductor-containing layers) of Examples 1 to 10 had a larger dielectric constant than the dielectric layer of Comparative Example 1 even at a frequency as low as 1 Hz and a frequency as high as 10,000 Hz. The dielectric layers of Examples 1 to 10 also had higher volume resistivity than the dielectric layer of Comparative Example 1. The actuators of Examples 1 to 10 therefore had a larger generated force and higher dielectric breakdown strength as compared to the actuator of Comparative Example 1.

The dielectric layer of Example 3 contains insulating particles. The dielectric layer of Example 3 therefore had higher volume resistivity than the dielectric layer of Example 2 containing the same amount of inorganic semiconductor powder as the dielectric layer of Example 3. Accordingly, the actuator of Example 3 had higher dielectric breakdown strength than the actuator of Example 2. The dielectric layer of Example 4 contains a large amount of inorganic semiconductor powder. The dielectric layer of Example 4 therefore had a larger dielectric constant than the dielectric layers of Examples 1 to 3, but the volume resistivity of the dielectric layer of Example 4 was about the same or smaller than that of the dielectric layers of Examples 1 to 3. Accordingly, the actuator of Example 4 had lower dielectric breakdown strength but had a larger generated force per unit field strength (generated force/dielectric breakdown strength) as compared to the actuators of Examples 1 to 3. The amount of semiconductor and the amount of insulating particles are thus determined as appropriate according to the dielectric breakdown strength or generated force required for each application.

The dielectric layer (semiconductor-containing layer) of Example 11 including a p-type organic semiconductor had a larger dielectric constant but lower volume resistivity as compared to the dielectric layer of Comparative Example 1. However, the actuator of Example 11 had a larger generated force and higher dielectric breakdown strength than the actuator of Comparative Example 1.

The dielectric layers of Comparative Examples 2, 3 contain a large amount of insulating particles instead of semiconductor particles. The dielectric layers of Comparative Examples 2, 3 therefore had higher volume resistivity than the dielectric layer of Comparative Example 1, but had about the same dielectric constant as the dielectric layer of Comparative Example 1. The actuator of Comparative Example 2 therefore does not have the effect of increasing the generated force. The dielectric layer of Comparative Example 4 containing ion components had an increased dielectric constant at a frequency as low as 1 Hz, but had about the same dielectric constant as the other comparative examples at the higher frequencies. The dielectric layer of Comparative Example 4 had lower volume resistivity than the dielectric layers of Comparative Examples 1 to 3. Accordingly, the actuator of Comparative Example 4 had a smaller maximum generated force and lower dielectric breakdown strength than the actuators of Comparative Examples 1 to 3.

As described above, it was verified that the use of a semiconductor-containing layer as a dielectric layer increased the generated force of an actuator and improves resistance to dielectric breakdown.

### INDUSTRIAL APPLICABILITY

The flexible transducer of the present invention can be widely used as an actuator, sensor, power-generating element, etc. which carries out conversion between mechanical energy and electrical energy, or a speaker, microphone, noise canceller, etc. which carries out conversion between acoustic energy and electrical energy. In particular, the flexible transducer of the present invention is preferable as a flexible actuator that is used for artificial muscles for industrial applications, medical applications, welfare robots, power-assisted suits, etc., small pumps for cooling electronic parts, for medical applications, etc., medical instruments, etc.

1. A flexible transducer, characterized by comprising:
a dielectric layer including a semiconductor-containing layer that contains an elastomer and at least one of an inorganic semiconductor and an organic semiconductor; and
a pair of electrodes disposed with the dielectric layer interposed therebetween, and containing a binder and a conductive material, wherein
the inorganic semiconductor is particles of a metal oxide doped with a different kind of element.

2. The flexible transducer according to claim 1, wherein
the semiconductor-containing layer has volume resistivity of 10¹⁰ Ω·cm or more.

3. The flexible transducer according to claim 1, wherein
the semiconductor-containing layer contains the inorganic semiconductor.

4. The flexible transducer according to claim 1, wherein
the semiconductor-containing layer contains the organic semiconductor.

5. The flexible transducer according to claim 1, wherein
the semiconductor-containing layer further contains insulating particles.

6. The flexible transducer according to claim 1, wherein
the semiconductor-containing layer is formed of a p-type semiconductor-containing layer containing a p-type semiconductor and an n-type semiconductor-containing layer containing an n-type semiconductor,
the dielectric layer is a stack of the p-type semiconductor-containing layer and the n-type semiconductor-containing layer.

7. The flexible transducer according to claim 1, wherein
the dielectric layer further includes a high resistance layer containing an elastomer and having volume resistivity of 10¹² Ω·cm or more.

8. The flexible transducer according to claim 7, wherein
the semiconductor-containing layer is formed of a p-type semiconductor-containing layer containing a p-type semiconductor and an n-type semiconductor-containing layer containing an n-type semiconductor, and
the high resistance layer is disposed between the p-type semiconductor-containing layer and the n-type semiconductor-containing layer.

9. The flexible transducer according to claim 1, wherein
the flexible transducer is an electrostrictive transducer.
